(19) United States
(12) Patent Application Publication
(10) Pub. No.: US 2025/0343107 A1
(43) Pub. Date: Nov. 6, 2025

(54) THROUGH-CHIP VIAS EXTENDING THROUGH MULTIPLE CHIPS FOR TOP-DOWN POWER REDISTRIBUTION

(71) Applicant: International Business Machines Corporation, Armonk, NY (US)

(72) Inventors: Mukta Ghate Farooq, Hopewell Junction, NY (US); Arvind Kumar, Stamford, CT (US); John W. Golz, Hopewell Junction, NY (US)

(21) Appl. No.: 18/653,535

(22) Filed: May 2, 2024

(51) Int. Cl. H01L 23/48; H01L 21/48; H01L 23/00; H01L 23/367; H01L 23/528; H01L 25/18

(52) U.S. Cl. CPC H01L 23/481; H01L 21/486; H01L 23/367; H01L 23/5286; H01L 25/18; H01L 24/13; H01L 24/16; H01L 24/32; H01L 24/73; H01L 2224/13147; H01L 2224/16145; H01L 2224/32145; H01L 2224/73204; H01L 2225/06513; H01L 2225/06589; H01L 2924/1431

(57) ABSTRACT

A semiconductor structure that includes a plurality of memory dies in a stacked configuration, and at least one through-chip via (TCV) that extends through the plurality of memory dies where the at least one TCV is adapted to provide power to the plurality of memory dies.

### BACKGROUND

The present disclosure relates to three-dimensional (3D) memory devices and fabrication methods thereof.

Semiconductor manufacturers strive to reduce the size of die packages to fit within the space constraints of electronic devices while increasing the functional capacity of each package to meet operating parameters. One approach for increasing the processing power and/or storage capacity of a semiconductor package without substantially increasing the surface area covered by the package (i.e., the “footprint”) is to vertically stack multiple semiconductor dies (or “chips” or “wafers”) on top of one another in a single package. The dies in such vertically stacked packages can be interconnected by electrically coupling the bond pads of the individual dies with the bond pads of adjacent dies using through-silicon vias (TSVs).

### SUMMARY

According to some embodiments of the disclosure, there is provided a semiconductor structure. The semiconductor structure includes a plurality of memory dies in a stacked configuration, and at least one continuous, through-chip via (TCV) that extends through the plurality of memory dies where the at least one TCV is adapted to provide power to the plurality of memory dies.

According to some embodiments of the disclosure, there is provided a semiconductor structure. The semiconductor structure includes: a plurality of memory dies in a stacked configuration, a logic die located above the plurality of memory dies, a plurality of TCVs that extend through the plurality of memory dies where the plurality of TCVs are adapted to provide power to the logic die, and a plurality of through-silicon vias (TSVs) extending through each of the plurality of memory dies and adapted to transmit power from the logic die to the plurality of memory dies.

According to some embodiments of the disclosure, there is provided a method of fabricating a semiconductor die assembly. The method includes a step of providing a memory die stack including a plurality of memory dies. Another step is providing a logic die located above the plurality of memory dies. A further step is forming a plurality of TCVs that extend through the plurality of memory dies where the at least one of the plurality of TCVs is adapted to provide power to the plurality of memory dies.

The above summary is not intended to describe each illustrated embodiment or every implementation of the present disclosure.

### BRIEF DESCRIPTION OF THE DRAWINGS

The drawings included in the present application are incorporated into, and form part of, the specification. They illustrate embodiments of the present disclosure and, along with the description, serve to explain the principles of the disclosure. The drawings are only illustrative of certain embodiments and do not limit the disclosure.

FIG. 1 illustrates a cross-sectional view of a semiconductor die assembly, in accordance with embodiments of the present disclosure.

FIG. 2 illustrates a cross-sectional view of a step in the fabrication of the semiconductor die assembly of FIG. 1, in accordance with embodiments of the disclosure.

FIG. 3 illustrates a cross-sectional view of a step in the fabrication of the semiconductor die assembly of FIG. 1, in accordance with embodiments of the disclosure.

FIG. 4 illustrates a cross-sectional view of a step in the fabrication of the semiconductor die assembly of FIG. 1, in accordance with embodiments of the disclosure.

FIG. 5 illustrates a cross-sectional view of a step in the fabrication of the semiconductor die assembly of FIG. 1, in accordance with embodiments of the disclosure.

FIG. 6 illustrates a cross-sectional view of a semiconductor die assembly, in accordance with embodiments of the present disclosure.

FIG. 7 illustrates a cross-sectional view of a semiconductor die assembly, in accordance with embodiments of the present disclosure.

FIG. 8 illustrates a cross-sectional view of a semiconductor die assembly, in accordance with embodiments of the present disclosure.

While the disclosure is amenable to various modifications and alternative forms, specifics thereof have been shown by way of example in the drawings and will be described in detail. It should be understood, however, that the intention is not to limit the disclosure to the particular embodiments described. On the contrary, the intention is to cover all modifications, equivalents, and alternatives falling within the spirit and scope of the disclosure.

### DETAILED DESCRIPTION

Aspects of the present disclosure relate generally to fabrication methods and resulting structures for semiconductor devices. More particularly, the present disclosure provides a semiconductor die assembly with through-chip vias (TCVs) extending through multiple chips (or “dies”) for top-down power redistribution. While the present disclosure is not necessarily limited to such applications, various aspects of the disclosure can be appreciated through a discussion of various examples using this context.

According to some embodiments of the disclosure, there is provided a semiconductor structure. The semiconductor structure includes a plurality of memory dies in a stacked configuration, and at least one continuous through-chip via (TCV) that extends through the plurality of memory dies where the at least one continuous TCV is adapted to provide power to the plurality of memory dies from the top down through a power redistribution bus in a logic die that is located on top of the plurality of memory dies. The location of the logic die atop the plurality of memory dies allows more efficient cooling of the logic die via a heat sink, for example.

According to some embodiments of the disclosure, there is provided a semiconductor structure. The semiconductor structure includes: a plurality of memory dies in a stacked configuration, a logic die located above the plurality of memory dies, a plurality of TCVs that extend through the plurality of memory dies where the plurality of TCVs are adapted to provide power to the logic die, and a plurality of through-silicon vias (TSVs) extending through each of the plurality of memory dies and adapted to transmit power from the logic die to the plurality of memory dies. The location of the logic die atop the plurality of memory dies allows more efficient cooling of the logic die via a heat sink, for example.

According to some embodiments of the disclosure, there is provided a method of fabricating a semiconductor die assembly. The method includes a step of providing a memory die stack including a plurality of memory dies. Another step is providing a logic die located above the plurality of memory dies. A further step is forming a plurality of TCVs that extend through the plurality of memory dies where the at least one of the plurality of TCVs is adapted to provide power to the plurality of memory dies. The location of the logic die atop the plurality of memory dies allows more efficient cooling of the logic die via a heat sink, for example.

It will be readily understood that the components of the present embodiments, as generally described and illustrated in the Figures herein, can be arranged and designed in a wide variety of different configurations. Thus, the following detailed description of the embodiments of the apparatus, system, method, and computer program product of the present embodiments, as presented in the Figures, is not intended to limit the scope of the embodiments, as claimed, but is merely representative of selected embodiments.

Reference throughout this specification to “a select embodiment,” “one embodiment,” or “an embodiment” means that a particular feature, structure, or characteristic described in connection with the embodiment is included in at least one embodiment. Thus, appearances of the phrases “a select embodiment,” “in one embodiment,” or “in an embodiment” in various places throughout this specification are not necessarily referring to the same embodiment. It should be understood that the various embodiments can be combined with one another, and that any one embodiment can be used to modify another embodiment.

The illustrated embodiments will be best understood by reference to the drawings, wherein like parts are designated by like numerals throughout. The following description is intended only by way of example, and simply illustrates certain selected embodiments of devices, systems, and processes that are consistent with the embodiments as claimed herein.

Specific details of embodiments of stacked semiconductor die assemblies with TCVs that pass through a stack of memory dies in order to allow a logic die to be located atop the stack of memory dies (or “chips”) are described below along with the associated methods of fabrication. The term “semiconductor die” generally refers to a die having integrated circuits or components, data storage elements, processing components, and/or other features manufactured on semiconductor substrates. For example, semiconductor dies can include integrated memory circuitry and/or logic circuitry. Semiconductor dies and/or other features in semiconductor die packages can be said to be in “thermal contact” with one another if the two structures can exchange energy through heat via, for example, conduction, convection and/or radiation. A person skilled in the relevant art will also understand that the technology may have additional embodiments, and that the technology may be practiced without several of the details of the embodiments described below with reference to the figures.

As used herein, the terms “vertical,” “lateral,” “upper” and “lower” can refer to relative directions or positions of features in the semiconductor die assemblies in view of the orientation shown in the Figures. For example, “upper” or “uppermost” can refer to a feature positioned closer to the top of a page than another feature. These terms, however, should be construed broadly to include semiconductor devices having other orientations, such as inverted or inclined orientations where top/bottom, over/under, above/below, up/down and left/right can be interchanged depending on the orientation.

Stacked memory die arrangements have several manufacturing challenges. For example, in vertically stacked memory die packages the heat from the individual dies is additive and the aggregated heat can be difficult to dissipate. The stacked memory die arrangement can also include locating a logic die, which creates heat, below the stacked memory die package. The stacked memory die arrangement can include through-silicon via (TSV) power connections with a high-power logic die that is placed on the bottom, below the vertically stacked memory die package, which can avoid voltage drop from series contact resistance through the multiple dies. A heat sink, which can help reduce heat build-up, can be placed on top and is, therefore, blocked from the logic die by the vertically stacked memory die package. Accordingly, a need exists for an arrangement that can provide effective heat reduction from both the logic die and the vertically stacked memory die package by the heat sink.

To address the needs and challenges, embodiments disclosed herein include a semiconductor die assembly comprising a package support substrate, a first semiconductor die mounted to the package support substrate, and a memory die stack including a plurality of semiconductor dies stacked on each other. A logic die is located atop the memory die stack. A heat sink can be located atop the logic die. In order to power the logic die atop the memory die stack, the semiconductor die assembly includes multiple TCVs that allow power to move upward from the package support substrate to the logic die and a power distribution bus (of the logic die). TCVs can be physically and/or electrically connected to the package support substrate and the logic die. TCVs can also be physically and/or electrically connected to the package support substrate and the power distribution bus in the logic die. TCVs can have a power potential. TCVs can be electrically connected to the memory die stack through the power distribution bus and a plurality of TSVs that are physically and/or electrically connected to the memory die stack. In order to power the memory die stack, the semiconductor die assembly includes TSVs that allow power to move downward from the power distribution bus (or logic die) into the memory die stack. TSV power connections are parallel between the logic die and the memory die stack. A heat sink can be located atop the logic die and can, therefore, provide effective heat reduction from the logic die and the memory die stack.

A TSV is a vertical electrical connection (via) that passes at least partly through a silicon wafer, chip or die. TSVs are high-performance interconnect techniques that enable connectivity between stacked, three-dimensional (3D) chips on substrates. A TCV is a vertical electrical connection (via) that is continuous and passes through a stack which may contain one or more entities such as memory dies, wafers or chips.

Embodiments of the present disclosure can include a semiconductor structure with a continuous TCV that extends through multiple chips (or multiple memory dies or layers) to provide power, ground, and/or signal to multiple chips. The TCV can feed power from a packaging substrate to at least two (or multiple) memory layers in a stacked structure of the multiple memory layers. The power to the memory layers can go through the TCV to an upper redistribution layer (or bus), then the power can further go through stacked vias (or TSVs) to power the memory layers. Electrically conductive through dielectric vias are used to transmit signal between any two near neighbor memory layers. At least one via can be used for a ground connection to the substrate. The stacked memory structure can be electrically joined to a top logic layer (or die). The at least one via can transmit power to the top logic layer through wires and metallurgical joints. One or more fine TSVs can be built in the memory layers, which can transmit power from a power distribution bus in the logic (or top) die to the memory layers. The stacked memory structure can include at least one of the electrically conductive TCVs, which comprises a through-dielectric and through-silicon via. The semiconductor structure can include a thermal lid and/or a heat sink that can be attached to the top logic layer. The semiconductor structure can include test pads and a test interface for testing the stacked memory structure alone.

Embodiments of the present disclosure can provide advantages that can be valuable to the semiconductor industry. An advantage of embodiments is a “logic-on-memory” configuration that can allow for cooling of high-power systems including a three-dimensional (3D) memory die stack with a logic die located on top. Another advantage of embodiments is effective power delivery to the logic die located on top and effective power distribution to the 3D memory die stack located below. A further advantage of embodiments is that resistance to the logic die is independent of the number of memory dies in the 3D memory die stack. An additional advantage of embodiments is that the logic die can be located directly next to a heat sink for effective cooling. Yet another advantage of embodiments is that a fabrication process can include testing of the 3D memory stacks prior to including them in a final semiconductor die assembly in order to only use the known good units, or known good stacks (KGSs), in the final assemblies. Another advantage of embodiments is that fabrication of the 3D memory die stack can be separated from processing to include TCVs and the logic die, and from final packaging to a substrate with a heat sink, for example. A further advantage of embodiments is enablement of use of memory stacks and a logic die from different technology nodes and manufacturers. Yet another advantage of embodiments is practicality or ease of implementation by a memory supplier because layouts of the memory dies do not have to change within the 3D memory die stack.

The semiconductor devices and methods for forming the same, in accordance with embodiments of the present disclosure, can be employed in applications, hardware, and/or electronic systems. Suitable hardware and systems for implementing embodiments of the invention may include, but are not limited to, personal computers, communication networks, electronic commerce systems, portable communications devices (e.g., cell and smart phones), solid-state media storage devices, functional circuitry, etc. Systems and hardware incorporating the semiconductor devices are contemplated embodiments of the invention. Given the teachings of embodiments of the invention provided herein, one of ordinary skill in the art will be able to contemplate other implementations and applications of embodiments of the invention.

It is to be understood that the present disclosure will be described in terms of a given illustrative architecture; however, other architectures, structures, substrate materials and process features and steps/blocks can be varied within the scope of the present disclosure. It should be noted that certain features cannot be shown in all figures for the sake of clarity. This is not intended to be interpreted as a limitation of any particular embodiment, or illustration, or scope of the claims.

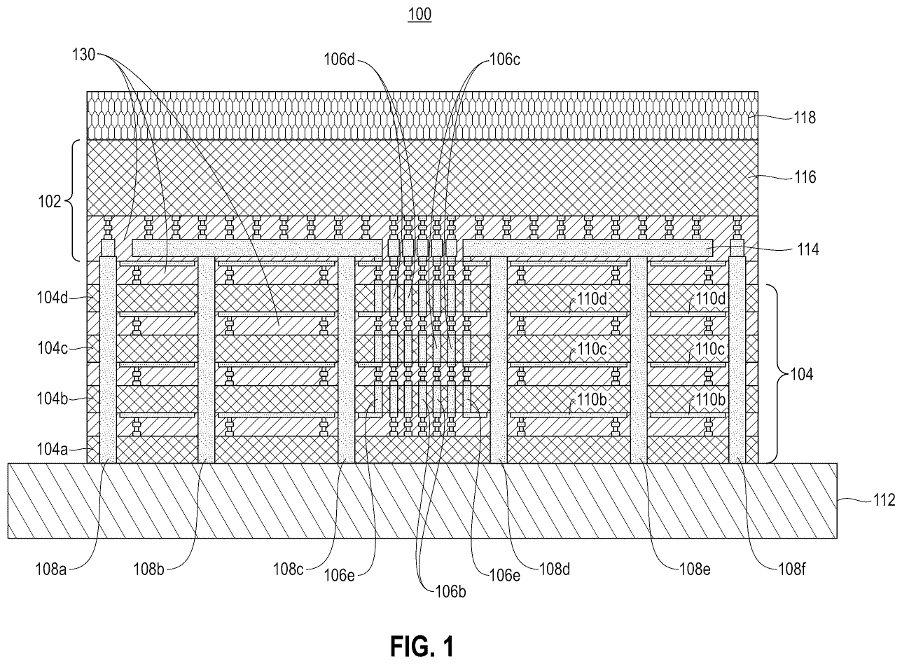

FIG. 1 illustrates a cross-sectional view of a semiconductor die assembly 100 in accordance with embodiments of the present disclosure. The semiconductor die assembly 100 is an example of a design including a logic die 102 located on top of a memory die stack 104 including a plurality of (or multiple) memory dies 104a-104d (collectively referred to as the memory die stack 104, including memory dies that are also referred to as “memory wafers” or “memory layers” or “memory chips”) that use multiple TSV-integration. This integration involves multiple, thin (or “fine”) TSVs 106b-106e extending in a parallel configuration through each of the memory dies 104b-104d, respectively. A width of the TSVs 106b-106e can be in a range of about 0.1 micrometer (μm) to 10 μm, for example, and can be described as “fine.”. The memory die stack 104 can include a plurality of (or multiple) TCVs 108a-108f that extend up from a packaging substrate 112 (or “laminate” or “substrate”) to a power distribution bus 114 (or “bus”) that is part of the logic die 102 or to a logic die substrate 116 that is also part of the logic die 102. The TCVs 108a-108f can be described as “wide” or “large” and are wider across as compared to the width of the TSVs 106b-106e in the semiconductor die assembly 100. A width of the TCVs 108a-108f can be in a range of about 1 μm to 1000 μm, for example. The TCVs 108b, 108c can, for example, be ground TCVs, and the TCVs 108a, 108d can be power TCVs, for example. The power distribution bus 114 can be described as a thick or large bus. The TSVs 106b-106e can carry power down from the power distribution bus 114 to the memory dies 104b-104d. Thin, power distribution layers 110b-110d can be associated with the memory dies 104b-104d, respectively. Input/outputs (I/Os) either to or from the logic die substrate 116 utilize the TCVs 108a, 108f. Power can move up from the packaging substrate 112 and into the logic die substrate 116 and the power distribution bus 114 through the TCVs 108, and then from the power distribution bus 114 the power can be redistributed and sent down into the memory dies 104a-104d via a top-level back end-of-line (BEOL) through the TSVs 106. A heat sink 118 can be located on top of the logic die 102 in order to remove heat from the logic die 102 and the memory die stack 104. In between other components in the semiconductor die assembly 100, there can be an underfill 130, which can be made of any suitable material.

A high speed serializer/deserializer (SerDes) on the logic die 102 can result from lower density, large TCVs such as the TCVs 108, which can be less disruptive for a memory vendor fabricating the memory die stack 104. Accordingly, the memory dies 104a-104d do not have their layouts changed within the memory die stack 104.

Keep-out zones (KOZs) can be used in fabrication process of the semiconductor die assembly 100 to establish portions in the memory dies 104b-104d that will eventually include the TCVs 108a-f, which can be formed after stacking of the memory dies 104a-104d. The KOZs (not shown in FIG. 1) can be made at a certain periodicity in each of the memory dies 104a-104d to anticipate formation of the power and the ground TCVs 108a-108f, for example. The KOZs establish areas where no other devices can be placed around the eventual TCV within each of the KOZs. The KOZs are conventionally defined as a circle centered at the center of the TCV and having a radius equal to the largest distance (over all angular positions) from the center of the TCV. The TCVs 108a-f can be formed in the KOZs and are shown as formed in FIG. 1.

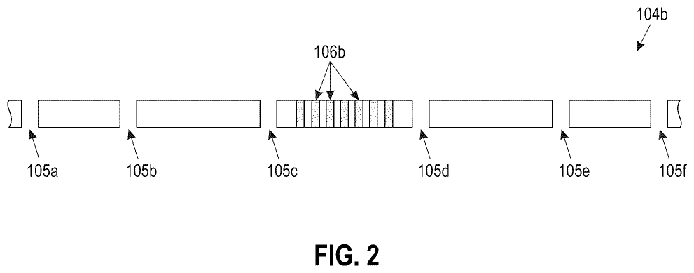

An example process flow for fabricating the semiconductor die assembly 100 depicted in FIG. 1 will now be described in conjunction with FIGS. 2-6.

FIG. 2 illustrates a cross-sectional view of a step in the fabrication of the semiconductor die assembly 100 of FIG. 1, in accordance with embodiments of the disclosure. The figure includes one memory die layer, which corresponds to a layer in FIG. 1 of the memory die stack 104 that is, for example, the memory die 104b. The memory die 104b is shown with the TSVs 106b that can already be included in the memory die 104b when it comes from a memory vendor or supplier. The memory die 104b can be made of silicon (Si), for example. The TSVs 106b can be included in the memory die 104b using a combination of etching, such as the Bosch process, reactive ion etching (RIE), insulator deposition, metallic liner and seed deposition, and copper plating. When the memory die 104b layer arrives from the memory vendor or supplier, for example, the TSVs 106b can include solder (not shown) located on top of and/or the bottom of the TSVs 106b for eventual copper hybrid enabled connections between the memory die 104b and another adjacent memory die (such as the memory die 104c in FIG. 1) in the memory die stack 104. The connection can be called a “solder drop” or a “copper hybrid bond” (“Cu HB”). There are multiple KOZs 105a-105f (collectively referred to as KOZs 105) extending through the memory die 104b in areas of the memory die 104b where the TCVs (such as TCVs 108a-108f in FIG. 1) are anticipated being located post-stacking.

A predetermined number of memory dies, such as the memory dies 104b, 104c, 104d can be prepared as described above. The memory die layers, such as the memory dies 104a-104d of FIG. 1, can be thinned, stacked and joined by solder drops or interconnects or Cu HB. In order to thin each memory die, the thinning can occur with the memory die is attached to a carrier and can be released after thinning. Next, another memory die on a carrier can be thinned in a sequential way. Wafer-by-wafer, or die-by-die, the memory die stack can be built up to a desired level with connections being made between successive memory dies or wafers. The memory die stack can be treated as a single wafer, which simplifies the handling process. Thin wafers can be difficult to deal with, as they are 50-100 microns or thinner. It is much easier to treat the memory die stack like a single wafer. It has the structural integrity to take care of any of the handling that occurs. The resulting memory die stack can be shipped to a facility for outsourced semiconductor assembly and testing (OSAT). An OSAT is a third-party service that suppliers offer, which consists of semiconductor assembly, packaging and testing of integrated circuits (ICs).

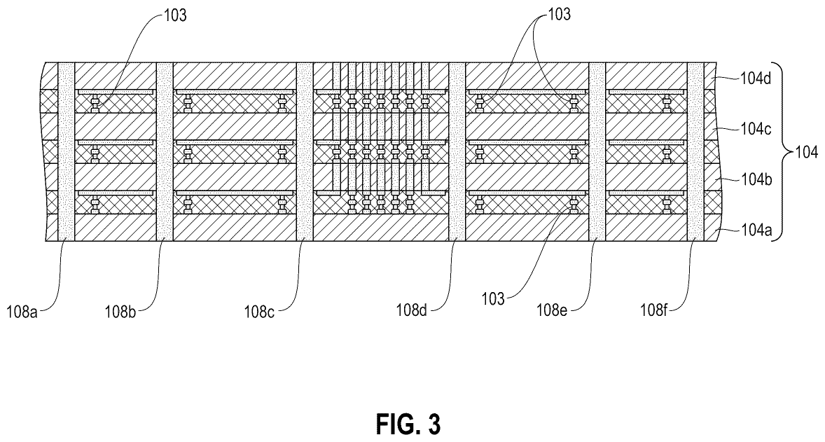

FIG. 3 shows a cross-sectional view of a resulting structure (known as a “stacked memory wafer complex”) resulting from the steps described above. in the fabrication of the semiconductor die assembly 100 of FIG. 1, in accordance with embodiments of the disclosure. In order to form the TCVs 108a-108f in the memory die stack 104, the KOZs 105a-105f (as in FIG. 2) can be etched. The etching process can be engineered and programmed. The etching can involve alternating BEOL etching and silicone etching. A moisture oxidation collar may have been previously built around the KOZs 105a-105f (in FIG. 2) in order to protect dielectrics of the BEOL during the etching. In further formation of the TCVs 108a-108f, TCV insulation, diffusion barrier/seed deposition and copper (Cu) plating can be used. A chemical mechanical planarization (or polishing) (CMP) process can follow.

There are multiple connectors 103 connecting features of the structure shown in FIG. 3 that are made during the fabrication process. The connectors 103 can be BEOL structures or copper hybrid bond pads or structures. These connectors can be made using standard BEOL processing such as plating of copper followed by CMP.

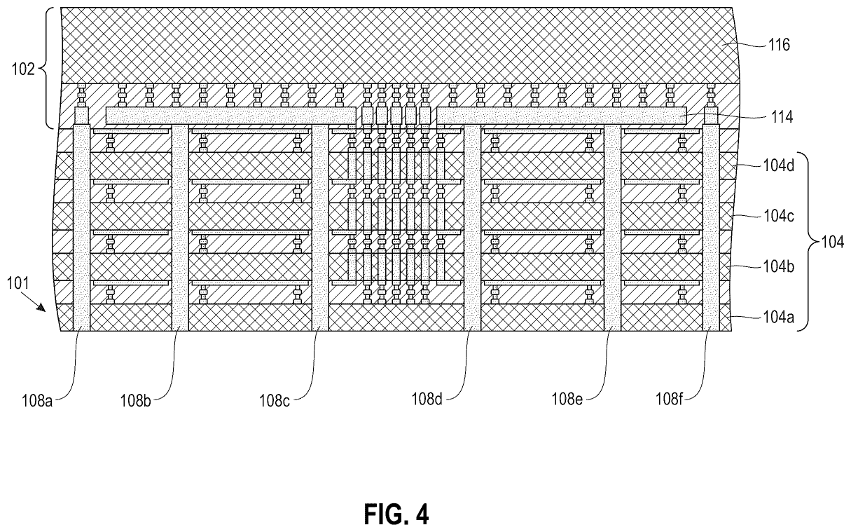

FIG. 4 illustrates a cross-sectional view of a step in the fabrication of the semiconductor die assembly 100 of FIG. 1, in accordance with embodiments of the disclosure. As shown, the logic die 102 is located on a top of the structure shown in FIG. 3. In order to do so, an under-bump metallization (UBM) process can be used. In addition, soldering or some other joining method can be used to join the logic die 102. The power distribution bus 114 (BEOL level), as part of the logic die 102, can be a BEOL level. It is an entity that is used to distribute the power that eventually can come up from a packaging substrate (such as packaging substrate 112 in FIG. 1).

In order to form the structure in FIG. 4, the structure of FIG. 3 can be attached to a temporary carrier or held in a fixture. Testing can then be performed on the structure in order to identify KGSs. Testing can include a program that can identify those areas that are not as good and those can be further designated to only receive dummy dies. Information regarding KGSs can be forwarded for final assembly. A benefit of using KGSs can improve final yield results. Grind side final operations can be performed on the structure. A grind side of the structure in FIG. 4 is indicated by 101. The grind side operations can include deposition of oxide/nitride films followed by TCV reveal and solder deposition through resist stencil plating or ball drop. Next, the complete wafer can be ready for the logic die 102 joining, which can be die to wafer (D2 W) or wafer to wafer (W2 W) using solder or Cu HB. After joining, underfill and/or molding can be used, if needed. The structure of FIG. 4 can be diced into logic-on-memory cubes that can be joined to packaging substrates.

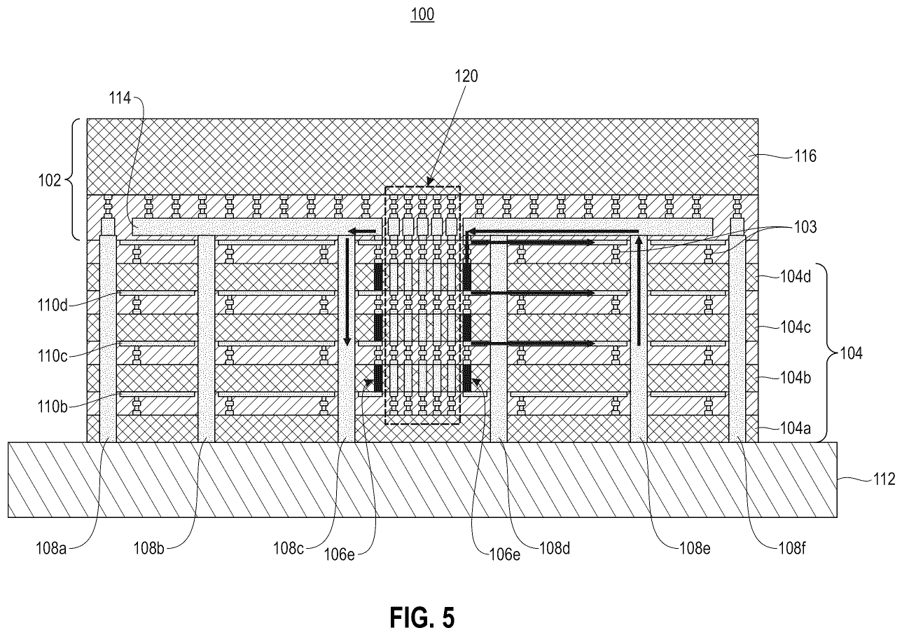

FIG. 5 illustrates a cross-sectional view of a step in the fabrication of the semiconductor die assembly 100 of FIG. 1, in accordance with embodiments of the disclosure. It shows one (1) logic-on-memory cube, diced from the structure shown in FIG. 4, for example, located atop and adjoined to the packaging substrate 112. The logic die 102 is on top, seated on the connectors 103 to underlying structure.

Power can be delivered through the I/O TCVs 108a, 108f to the logic die 102 from the packaging substrate 112. The packaging substrate 112 can be an organic packaging substrate or laminate, for example. Signal and power from the packaging substrate 112 travels through and moves up through the TCVs 108 to the logic die substrate 116 (of the logic die 102) or the power distribution bus 114, where it is needed. Arrows in the figure show how the power can move, for example, from the packaging substrate 112 through the TCV 108e, which is a power TCV, to the power distribution bus 114. From the power distribution bus 114, power can be distributed and sent down to the various memory levels, or the memory dies 104b-104d. Connectors at various points allow the power to be used at any chip level, or by any of the memory dies 104a-d, and where it is needed. Arrows in the figure show how the power can move down from the power distribution bus 114 through the TSVs 106 (specifically outer TSVs 106e). Additional arrows show how power can move outward through the BEOL paths through the memory dies 104b-104d either in front of or behind (in the page or out of the page, in the figure) the TCVs 108a-108f. The outer TSVs 106e are outside a central portion (indicated by a dashed-line box) of the memory die stack 104, which is known as a high-density memory bus 120. In the high-density memory bus 120, there are multiple types of connections. The TSVs 106b-106e are fine signal TSVs that are capable of communicating signals down the memory die stack 104 from the logic die 102. In the figure, an arrow also shows how power or signals can also travel down a TCV, such as the ground TCV 108c back to the packaging substrate 112. The memory dies 104b-104d also include thin power distribution components 110b-110d that are shown located on a lower side of each of the memory dies 104b-104d, respectively. The power distribution components 110b-110d are lines made by standard BEOL techniques.

In order to cool the logic die 102 in the structure of FIG. 5, a thermal lid and a heat sink can be located above and in contact with the logic die 102. As shown in FIG. 1, the heat sink 118 is located atop the logic die 102 in a step in the fabrication of the semiconductor die assembly 100. Any suitable heat sink or cooling mechanism is contemplated by the present disclosure.

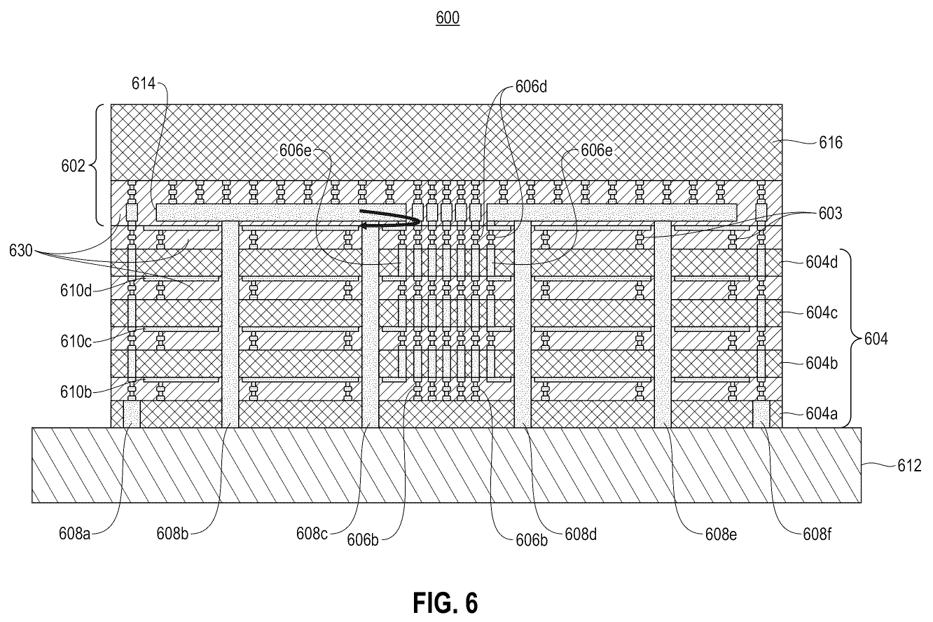

FIG. 6 illustrates a cross-sectional view of a semiconductor die assembly 600 in accordance with embodiments of the present disclosure. It shows the semiconductor die assembly 600 including a logic die 602 located on top of underlying structure that includes a memory die stack 604. The semiconductor die assembly 600 includes a wide, parallel I/O interface on the logic die 602 using higher density small TSVs. Connectors 603 can be located between a power distribution bus 614 of the logic die 602 and the memory die stack 604. Similar connectors can be located between the memory layers of the memory die stack 604, etc. The advantage of this method is that the connections between consecutive layers may be accomplished by the same or similar connectors as those used to connect consecutive KGSs.

Power can be delivered upward through I/O TCVs 608a, 608f to the logic die 602 from a packaging substrate 612. As compared to the embodiment of FIG. 1, the I/O TCVs 608a, 608f are fine or narrow. A width of the I/O TCVs 608a, 608f can be in a range of about 0.1 micrometer (μm) to 10 μm, for example. Signal and power from the substrate 612 travels through and moves up through TCVs 608a-608f to the logic die 602 or the power distribution bus 614, where it is needed. An arrow in the figure shows the direction of current travel, which is from the power distribution bus to the BEOL line. From the power distribution bus 614, power can be distributed and sent down to the various memory levels, or memory dies 604b-604d. Connectors at various points allow the power to be used at any chip level or the memory die stack 604 where it is needed. Power can move down from the power distribution bus 614 through TSVs 606 (specifically outer TSVs 606e). The outer TSVs 606e are outside a central portion of the memory die stack 604, which is known as a high-density memory bus. In the high-density memory bus, there are multiple types of connections. The TSVs 606b-606d are fine signal TSVs that are capable of communicating signals down the memory die stack 604 from the logic die 602. In between other components in the semiconductor die assembly 600, there can be an underfill 630, which can be made of any suitable material.

In order to cool the logic die 602 in the semiconductor die assembly 600 of FIG. 6, a thermal lid and a heat sink (not shown) can be located above and in contact with the logic die 602. Any suitable heat sink or cooling mechanism is contemplated by the present disclosure.

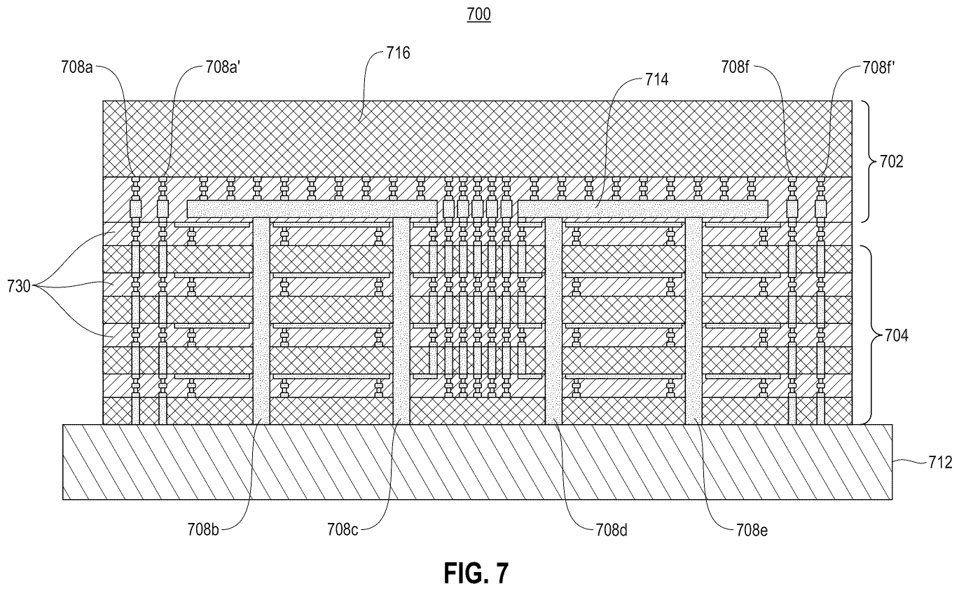

FIG. 7 illustrates a cross-sectional view of a semiconductor die assembly 700 in accordance with embodiments of the present disclosure. It shows the semiconductor die assembly 700 that is significantly similar to the semiconductor die assembly 600 of FIG. 6, and the discussion above with regards to corresponding components applies to the semiconductor die assembly 700. For example, the semiconductor die assembly 700 includes a logic die 702 located on top of underlying structure that includes a memory die stack 704. The semiconductor die assembly 700 differs from semiconductor die assembly 600, for example, by including higher density, small, thin or narrow I/O TCVs 708a, 708a′, 708f, 708f′ that deliver power upward to the logic die 702 from a packaging substrate 712. Although four (4) small I/O TCVs 708a, 708a′, 708f, 708f are shown, any suitable number of small thin or narrow I/O TCVs are contemplated by the present disclosure. A width of the I/O TCVs 708a, 708a′, 708f, 708f can be in a range of about 0.1 micrometer (μm) to 10 μm, for example. Signal and power from the packaging substrate 712 travels through and moves up through TCVs 708a-708f, 708a′, 708f′ to a logic die substrate 716 or a power distribution bus 714, where it is needed. In between other components in the semiconductor die assembly 700, there can be an underfill 730, which can be made of any suitable material.

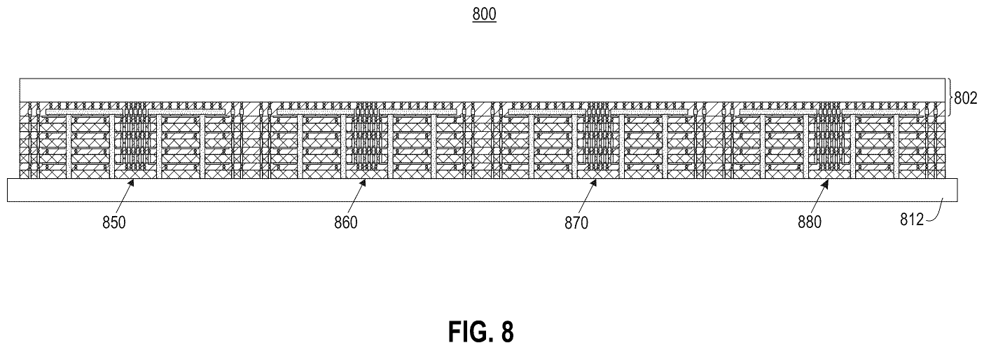

FIG. 8 illustrates a cross-sectional view of a semiconductor die assembly 800 in accordance with embodiments of the present disclosure. The semiconductor die assembly 800 includes a single packaging substrate 812 and a single logic die 802. Multiple memory die stacks are included, such as a first memory die stack 850, a second memory die stack 860, a third memory die stack 870 and a fourth memory die stack 880 with the single logic die 802 and the single packaging substrate 812. Any suitable number of memory die stacks are contemplated and are not limited to the number shown. The memory die stacks 850, 860, 870, 880 shown are similar to the memory die stack 704 of the semiconductor die assembly 700 (FIG. 7). However, any of the memory die stack configurations included in the present disclosure or contemplated by the present disclosure and can alternatively be used in the semiconductor die assembly 800.

Embodiments of the present disclosure can include a method of fabricating a semiconductor die assembly (such as the semiconductor die assembly 100 of FIG. 1) of the present disclosure. An operation of the method can be providing a memory die stack (such as the memory die stack 104) including a plurality of memory dies (such as the memory dies 104a-104d). Another operation can be providing a logic die (such as the logic die 102) located above the plurality of memory dies (such as the memory dies 104a-104d). A further operation can be forming a plurality of continuous through-chip via (TCVs) (such as the TCVs 108a-108f) that extend through the plurality of memory dies (such as the memory dies 104a-104d) wherein the at least one of the plurality of TCVs (such as the TCVs 108a-108f) is adapted to provide power to the plurality of memory dies (such as the memory dies 104a-104d). Another operation can be providing a substrate (such as the packaging substrate 112) located below the memory die stack (such as the memory die stack 104), wherein at least one of the plurality of TCVs (such as the TCVs 108a-108f) is adapted to provide the power from the substrate (such as the packaging substrate 112) to the logic die (such as the logic die 102). An additional operation can be providing a heat sink (such as the heat sink 118) located above the logic die (such as the logic die 102) and adapted to remove heat from the logic die (such as the logic die 102) and from the memory die stack (such as the memory die stack 104). Another operation can be providing a power distribution bus (such as the power distribution bus 114) located above the memory die stack (such as memory die stack 104) and adapted to provide power to the plurality of memory dies (such as the memory dies 104a-104d). Yet another operation can be providing a plurality of through-silicon vias (TSVs) (such as the TSVs 106a-106e) extending through each of the plurality of memory dies (such as the memory dies 104a-104d) and adapted to transmit power from the logic die (such as the logic die 102) to the plurality of memory dies (such as the memory dies 104a-104d).

For purposes of this description, certain aspects, advantages, and novel features of the embodiments of this disclosure are described herein. The disclosed processes, and systems should not be construed as being limiting in any way. Instead, the present disclosure is directed toward all novel and nonobvious features and aspects of the various disclosed embodiments, alone and in various combinations and sub-combinations with one another. The processes, and systems are not limited to any specific aspect or feature or combination thereof, nor do the disclosed embodiments require that any one or more specific advantages be present, or problems be solved.

Although the operations of some of the disclosed embodiments are described in a particular, sequential order for convenient presentation, it should be understood that this manner of description encompasses rearrangement, unless a particular ordering is required by specific language set forth below. For example, operations described sequentially can in some cases be rearranged or performed concurrently. Moreover, for the sake of simplicity, the attached figures may not show the various ways in which the disclosed processes can be used in conjunction with other processes. Additionally, the description sometimes uses terms like “provide” or “achieve” to describe the disclosed processes. These terms are high-level abstractions of the actual operations that are performed. The actual operations that correspond to these terms can vary depending on the particular implementation and are readily discernible by one of ordinary skill in the art.

As used in this application and in the claims, the singular forms “a,” “an,” and “the” include the plural forms unless the context clearly dictates otherwise. Additionally, the term “includes” means “comprises.”

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to explain the principles of the embodiments, the practical application or technical improvement over technologies found in the marketplace, or to enable others of ordinary skill in the art to understand the embodiments disclosed herein.

What is claimed is:

1. A semiconductor structure, comprising:
a plurality of memory dies in a stacked configuration; and
at least one through-chip via (TCV) that extends through the plurality of memory dies wherein the at least one TCV is adapted to provide power to the plurality of memory dies.

2. The semiconductor structure of claim 1, further comprising:
a substrate, wherein the at least one TCV that is adapted to provide the power from the substrate to a power distribution bus, wherein the power distribution bus is located above the plurality of memory dies and is connected to at least one through-silicon via (TSV) that extends through one of the plurality of memory dies and are adapted to provide the power from the substrate, through the power distribution bus and to the plurality of memory dies.

3. The semiconductor structure of claim 2, further comprising:
a logic die located above the power distribution bus, wherein the at least one TCV is adapted to provide power to the logic die.

4. The semiconductor structure of claim 3, further comprising:
a heat sink located above the logic die and adapted to remove heat from the logic die and the plurality of memory dies.

5. The semiconductor structure of claim 1, wherein the at least one TCV is adapted to provide a ground connection to a substrate.

6. The semiconductor structure of claim 1, wherein the at least one TCV is adapted to provide signals to the plurality of memory dies.

7. The semiconductor structure of claim 1, further comprising a plurality of through-silicon vias (TSVs) extending through each of the plurality of memory dies, wherein the plurality of TSVs is adapted to transmit signal between any two memory dies of the plurality of memory dies that are located next to each other.

8. The semiconductor structure of claim 1, further comprising:
a logic die located above the plurality of memory dies and electrically joined to the logic die.

9. A semiconductor structure, comprising:
a plurality of memory dies in a stacked configuration;
a logic die located above the plurality of memory dies;
a plurality of through-chip vias (TCVs) that extend through the plurality of memory dies wherein the plurality of TCVs are adapted to provide power to the logic die; and
a plurality of through-silicon vias (TSVs) extending through each of the plurality of memory dies and adapted to transmit power from the logic die to the plurality of memory dies.

10. The semiconductor structure of claim 9, further comprising:
a substrate located below the plurality of memory dies, wherein at least one of the plurality of TCVs is adapted to provide the power from the substrate to the logic die.

11. The semiconductor structure of claim 10, wherein at least one of the plurality of TCVs is adapted to provide a ground connection to the substrate.

12. The semiconductor structure of claim 9, further comprising:
a heat sink located above the logic die and adapted to remove heat from the logic die and the plurality of memory dies.

13. The semiconductor structure of claim 9, further comprising:
a power distribution bus located above the plurality of memory dies and adapted to provide power to the plurality of memory dies.

14. The semiconductor structure of claim 9, wherein the plurality of TSVs is adapted to transmit signals between any two memory dies of the plurality of memory dies that are located next to each other.

15. The semiconductor structure of claim 9, wherein the logic die is electrically joined to the plurality of memory dies.

16. A method of fabricating a semiconductor die assembly, comprising:
providing a memory die stack including a plurality of memory dies;
providing a logic die located above the plurality of memory dies;
forming a plurality of through-chip via (TCVs) that extend through the plurality of memory dies wherein at least one of the plurality of TCVs is adapted to provide power to the plurality of memory dies.

17. The method of claim 16, further comprising:
providing a substrate located below the memory die stack, wherein the at least one of the plurality of TCVs is adapted to provide the power from the substrate to the logic die.

18. The method of claim 16, further comprising:
providing a heat sink located above the logic die and adapted to remove heat from the logic die and from the plurality of memory dies.

19. The method of claim 16, further comprising:
providing a power distribution bus located above the memory die stack and adapted to provide the power to the plurality of memory dies.

20. The method of claim 16, further comprising:
providing a plurality of through-silicon vias (TSVs) extending through each of the plurality of memory dies and adapted to transmit the power from the logic die to the plurality of memory dies.
